(19) United States
(12) Patent Application Publication
(10) Pub. No.: US 2014/0251411 A1
(43) Pub. Date: Sep. 11, 2014

(54) LARGE AREA PHOTOVOLTAIC ENERGY-COLLECTING WINDOW/SKYLIGHT

(71) Applicant: Qualcomm Mems Technologies, Inc., (US)

(72) Inventors: Suryaprakash Ganti, San Diego, CA (US); Fan Yang, San Diego, CA (US)

(73) Assignee: Qualcomm Mems Technologies, Inc., San Diego, CA (US)

(21) Appl. No.: 13/786,279

(22) Filed: Mar. 5, 2013

(51) Int. Cl. H01L 31/052; H01L 31/18; H01L 31/048

(52) U.S. Cl. CPC H01L 31/0522; H01L 31/0484; H01L 31/18
USPC 136/246; 136/251; 29/592.1

(57) ABSTRACT

This disclosure provides photovoltaic energy collecting systems, and methods of making such systems. In one implementation, an apparatus includes transmissive light collection panels, each panel having at least one photovoltaic cell on an edge of the panel. The panel is configured to pass through a first portion of incident light and use a second portion of incident light to generate photovoltaic energy. The apparatus also includes a first and second electrical output terminal, a first and second electrical bus, and a metallic frame assembly having multiple openings, each light collection panel being disposed in one of the openings. The frame assembly includes a cavity that houses the first and second electrical bus, the first electrical bus connected to each photovoltaic cell and to the first electrical output terminal, and the second electrical bus is connected to each photovoltaic cell and to the second electrical output terminal.

### TECHNICAL FIELD

This disclosure relates to the field of photovoltaic light collectors, and more particularly to devices that incorporate photovoltaic power generation into building structures.

### DESCRIPTION OF THE RELATED TECHNOLOGY

Solar energy is a renewable source of energy that can be converted into other forms of energy such as heat and electricity. Some drawbacks in using solar energy as a reliable source of renewable energy are low efficiency in collecting solar energy and in converting light energy to heat or electricity, space requirements when locating solar panels on existing or new buildings, and the variation in the solar energy collection depending on the time of the day and the month of the year.

A photovoltaic (PV) cell can be used to convert solar energy to electrical energy. PV cells can be made very thin such they are not as big and bulky as other devices that use solar energy. For example, PV cells can range in width and length from a few millimeters to 10's of centimeters. Although, the electrical output from an individual PV cell may range from, for example, a few milliwatts to a few watts, due to their compact size, multiple PV cells may be connected electrically and packaged to produce, in total, a significant amount of electricity. For example, multiple solar panels each including a plurality of PV cells can be used to produce sufficient electricity to satisfy the power needs of some homes.

Solar concentrators can be used to collect and focus solar energy to achieve higher conversion efficiency in PV cells. For example, parabolic mirrors can be used to collect and focus light on PV cells. Other types of lenses and mirrors can also be used to collect and focus light on PV cells. These devices can increase the light collection efficiency. But such systems tend to be bulky and heavy because the lenses and mirrors that are required to efficiently collect and focus sunlight may be large. However, for many applications such as, for example, providing electricity to residential and commercial properties, charging automobile batteries, and other navigation instruments, it is desirable that the light collectors and/or concentrators are compact in size.

PV materials are also increasingly replacing conventional construction materials in parts of residential and commercial buildings. PV materials incorporated in such building can function as principal or secondary sources of electrical power and help in achieving “zero-energy” consuming buildings. One of the currently available building-integrated photovoltaic (BIPV) products is a crystalline Si BIPV, which is made of an array of opaque crystalline Si cells sandwiched between two glass panels. Another available BIPV product is a thin film BIPV which is manufactured by blanket depositing PV film on a substrate and laser scribing of the deposited PV film from certain areas to leave some empty spaces and improve transmission. However, both available BIPV products described above may suffer from low transmission (5-20%) disruptive appearance. Additionally, the thin film BIPV may also be expensive to reasonably manufacture.

### SUMMARY

The systems, methods and devices of the disclosure each have several innovative aspects, no single one of which is solely responsible for the desirable attributes disclosed herein.

One innovative aspect of the subject matter described in this disclosure can be implemented in a photovoltaic energy collecting apparatus including a plurality of transmissive light collection panels, each of the light collection panels including at least one photovoltaic cell disposed along an edge of the light collection panel, each of the plurality of light collection panels configured to pass through a first portion of received incident light and use a second portion of received incident light to generate photovoltaic energy. The apparatus may further include a first electrical output terminal and a second electrical output terminal, a first electrical bus and a second electrical bus, and a metallic frame assembly including a plurality of openings, each of the plurality of light collection panels being disposed in one of the openings of the frame assembly such that the frame assembly surrounds and supports each light collection panel. In such an apparatus, a portion of the frame assembly that surrounds each of the plurality of light collection panels may include a cavity that houses the first electrical bus and the second electrical bus, the first electrical bus being electrically connected to each of the at least one photovoltaic cells and to the first electrical output terminal, and the second electrical bus being electrically connected to each of the at least one photovoltaic cells and to the second electrical output terminal. Each of the light collection panels may include a first optical layer having a top surface and a bottom surface, the top surface including a plurality of micro-lenses configured to focus incident sunlight received thereon, a second optical layer having a top surface and a bottom surface, the second optical layer disposed behind the first optical layer such that the bottom surface of the first optical layer is between the top surface of the first optical layer and the second optical layer and the top surface of the second optical layer is disposed facing the bottom surface of the first optical layer, the bottom surface of the second optical layer including a plurality of light turning features configured to redirect light incident thereon toward one or more edges of the second optical layer, and a gap between the first optical layer and the second optical layer. The at least one photovoltaic cell may be disposed along at least one edge of the second optical layer.

Other features may also be included in an energy collecting apparatus. The at least one photovoltaic cell may include at least one photovoltaic cell disposed on each of two opposite edges of the plurality of light collection panels. The at least one photovoltaic cell may include at least photovoltaic cell disposed on opposite edges of the second optical layer. The at least one photovoltaic cell includes a plurality of photovoltaic cells disposed on opposite edges of the second optical layer of the collection panels, and wherein the apparatus further comprises a plurality of printed circuit boards (PCB) each coupled to the plurality of photovoltaic cells disposed on one edge of the second optical layer of a collection panel, wherein each respective PCB is configured to electrically coupled to the plurality of photovoltaic cells to connect the plurality of photovoltaic cells in serial and provide two electrical output terminals for outputting power generated by the plurality of photovoltaic cells coupled to the PCB. One or more of the light collection panels may include integrated electronics and micro-inverters coupled to the printed circuit boards. The frame assembly may include spacers disposed between the each light collection panel first and second optical layers such that there is a gap therebetween. The frame assembly may include a plurality of I-frame shaped members, wherein the center of the I-frame shaped members includes the cavity, and wherein the top and bottom of the I-frame support the light collection panels. In some implementations, the first electrical bus and the second electrical bus are disposed in the cavity and connect to the first and second electrical terminals in the cavity, and wherein the first and second electrical terminals provide an electrical connection through the frame assembly. In some implementations, a portion of the frame assembly around each collection panel includes at least one aperture, and wherein the first and second terminals pass through the at least one aperture of the frame assembly and connect to the first electrical bus and the second electrical bus in the cavity. In some implementations, a portion of the frame assembly around each collection panel includes two electrical connectors, and wherein the first and second terminals are electrically connected to the first electrical bus and the second electrical bus, respectively, by the two electrical connectors. The collection panels described herein may also include one or more turning feature integrated (TFI) wires disposed in the turning features of a first light collection panel, the one or more TFI wires electrically connected to one of the first electrical bus and the second electrical bus. In some implementations, the light collecting apparatus may include one or more TFI wires disposed in turning features of a second light collection panel, the TFI wires of the first light collection panel being electrically connected to TFI wires in the second light collection panel. The TFI wires of the first and second light collection panels may electrically connect photovoltaic cells of the first and second light collection panels in parallel. In some implementations, the TFI wires of the first and second light collection panels are used to electrically connect photovoltaic cells of the first and second light collection panels in series. In various implementations, the apparatus is configured as one of a skylight, a window, a door, and a wall.

Another innovation includes a method of manufacturing a photovoltaic light collecting apparatus. The method may include providing a metallic frame assembly including a plurality of openings, wherein a portion of the frame assembly that surrounds each of the plurality of openings includes a cavity, positioning at least one photovoltaic (PV) cell along at least a portion of the frame in each opening, disposing in each of the plurality of openings a transmissive panel such that the frame assembly surrounds and supports each of the transmissive panels, each transmissive panel including a first optical layer having a top surface and a bottom surface, the top surface including a plurality of micro-lenses configured to focus incident sunlight received thereon, a second optical layer having a top surface and a bottom surface, the second optical layer disposed behind the first optical layer such that the bottom surface of the first optical layer is between the top surface of the first optical layer and the second optical layer and the top surface of the second optical layer is disposed facing the bottom surface of the first optical layer, the bottom surface of the second optical layer including a plurality of light turning features configured to redirect light incident thereon toward one or more edges of the second optical layer, a gap between the first optical layer and the second optical layer. The at least one photovoltaic cell may be disposed along at least one edge of the second optical layer such that the at least one photovoltaic cell receives light directed towards the edge of the second optical layer, the at least one photovoltaic cell having a first electrical output terminal and a second electrical output terminal. Such a method may further include disposing a first electrical bus and a second electrical bus in the cavity of the frame assembly, and connecting the at least one photovoltaic cell to the first electrical bus and the second electrical bus using the first electrical output terminal and the second electrical output terminal, respectively.

In some implementations, the methods described herein may include connecting the at least one photovoltaic cell comprises providing an electrical connection that passes through the frame assembly comprising the apparatus is configured as one of a skylight, a window, a door, and a wall. In some implementations, methods may include providing an electrical connection that passes through the frame assembly includes disposing the first electrical output terminal and the second electrical output terminal through at least one aperture of the frame assembly. In some implementations, some methods may also include disposing wires within at least a portion of the light turning features and connecting the wires to the first electrical bus or the second electrical bus. In some implementations of such methods, the at least one photovoltaic cell includes a plurality of photovoltaic cells disposed on at least one edge of the second optical layer of the collection panels, and wherein the method further comprises coupling each of the plurality of photovoltaic cells along an edge of the second optical layer to a printed circuit board (PCB), wherein each respective PCB is configured to electrically coupled to the plurality of photovoltaic cells to connect the plurality of photovoltaic cells in serial, and wherein the first electrical output and the second electrical output provide electrical output terminals for power generated by the plurality of photovoltaic cells coupled to the PCB.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Example implementations disclosed herein are illustrated in the accompanying schematic drawings, which are for illustrative purposes only.

FIG. 1 is a plan view of a schematic illustrating one example of a framed photovoltaic (PV) panel assembly that includes twelve (12) 1′×1′ transmissive photovoltaic light collection panels in a 3×4 configuration.

FIG. 2 is a schematic illustrating a perspective view of an example of an implementation of a transmissive PV panel that includes a light guide and at least one PV cell that may be incorporated into a framed PV panel assembly, for example, as illustrated in FIG. 1.

FIG. 3 is a schematic illustrating a side view of another example of an implementation of a transmissive PV panel that can be incorporated into a framed panel assembly, for example, as illustrated in FIG. 1.

FIG. 4 is a schematic illustrating a side view of another example of an implementation of a transmissive PV panel that can be incorporated into a framed panel assembly, for example, as illustrated in FIG. 1.

FIG. 5 is a schematic illustrating a side view of a portion of an example of an implementation of a framed panel assembly, showing portions of a transmissive PV panels and a frame holding the transmissive PV panel.

FIG. 6 is a schematic illustrating a perspective view of an example of an implementation of electrical connections between PV cells and electrical contacts on a printed circuit board (PCB).

FIG. 7 is a schematic illustrating a side view of an example of an implementation of electrical connections between PV cells and electrical contacts on a printed circuit board (PCB).

FIG. 8 is a schematic illustrating an example implementation of a transmissive PV panel including a configuration of electrical wires that are integrated into turning features of the transmissive PV panel.

FIG. 9A is a schematic illustrating an example implementation of a transmissive PV panel showing solar cells of a transmissive PV panel connected in series.

FIG. 9B is a schematic illustrating an example implementation of a transmissive PV panel showing solar cells of a transmissive PV panel connected in parallel.

FIG. 10 is a schematic illustrating an example of an implementation of parallel electrical connections between six transmissive PV panels.

FIG. 11 is a flow chart illustrating an example of a method of manufacturing an implementation of a large area photovoltaic energy collecting window having a frame assembly and multiple light collection panels.

FIGS. 12A-12F are schematics illustrating cross-sectional views of portions of a frame assembly and PV transmissive panels.

Like reference numbers and designations in the various drawings may indicate like elements.

### DETAILED DESCRIPTION

The following detailed description is directed to certain implementations for the purposes of describing the innovative aspects. However, the teachings herein can be applied in a multitude of different ways. As will be apparent from the following description, the innovative aspects may be implemented in any device that is configured to receive radiation from a source and generate power using the radiation. More particularly, it is contemplated that the innovative aspects may be implemented in or associated with a variety of applications such as providing power to residential and commercial structures and properties, providing power to electronic devices such as laptops, personal digital assistants (PDA's), wrist watches, calculators, cell phones, camcorders, still and video cameras, MP3 players, etc. Some of the implementations described herein can be used in BIPV products such as windows, roofs, skylights, doors or façades. Some of the implementations described herein can be used to charge vehicle or watercraft batteries, power navigational instruments, to pump water and for solar thermal generation. The implementations described herein can also find use in aerospace and satellite applications, and other solar power generation applications.

Certain electrical hardware is needed for any building solar collection system. For a given solar energy collection system, the power generated can be increased by having additional PV cells in the system. Depending on the several factors, which may include how much electricity is being used by the building, the corresponding cost of the electricity, and the cost difference of different tier usage levels, increasing the amount of power generated may make the overall cost of the system more commercially feasible. Implementations described herein are directed to PV systems (or solar energy collection systems) and products that can be used for solar power generation, and that may be included in, or used instead of, a system that includes solar panels (for example, on the roof of a building). In some implementations, the described PV systems can be integrated into doors, skylights, walls, roofs, and other surfaces that are exposed to natural light, and that can efficiently absorb light and generate energy while also allowing transmission of incident sunlight to illuminate the inside of a building or other structure.

Depending on the design, architecture applications may require large size windows and/or skylights. However, the efficiency of a transmissive photovoltaic (PV) light collection panel often may decrease with size. As used herein, a light collection panel may be referred to as a “transmissive PV panel” or a “PV panel.” One example of such a light collection panel is a SoLux® panel. For applications that use a large area of glass, it can be beneficial to incorporate multiple smaller sized PV panels into a frame to form a larger integrated PV self-supporting panel of a desired size. Such an integrated frame assembly may be referred to herein as a framed PV panel assembly. A framed PV panel assembly may provide higher strength when compared against a single panel of glass of the same size with a surrounding frame. For doors, skylights and windows, the frame can be metallic (e.g., aluminum) to provide high structural strength and to help dissipate heat by thermal conduction.

The frame surrounding each of the PV panels can be designed to have a cavity in at least a portion of the frame. The cavity may be used to route wiring for the multiple PV panels in a framed PV panel assembly to an output connection, to other components used for solar power generation and storage, and/or to electrically connect two or more of the PV panels in an electrical serial or parallel configuration. The cavity can also reduce the overall weight of the frame such that a frame having a cavity has a lower weight than a solid frame (or a frame without a cavity) of a comparable size. In some implementations, the configuration of the frame can include an I-beam structure having a cavity disposed therein. Such an I-beam structure can be formed of two or more pieces. In some implementations, the two or more pieces may be coupled together after wiring and/or components are disposed within the cavity. For example, integrated electronics, micro-inverters, and other electrical components and wiring may be disposed safely and out of sight within the cavity of the frame structure, which may provide a longer lasting and aesthetically pleasing design.

In some implementations, a frame assembly may include spacers placed along the inside of an opening that receives the transmissive panes. Such spacers may be used to separate two (or more) transmissive panes of a PV panel at a desired distance, and based on the particular design, to achieve a desired amount of solar energy collection and light transmission. Each PV panel can include one or more PV cells disposed along one or more edges of the a transmissive pane that guides light to the PV cell(s), such that the PV cells are also against or near a portion of the frame supporting the edges of the transmissive panel. Wiring for the PV cells may be routed into the frame cavity through one or more apertures in the frame and connect to other electrical components inside the frame. By designing the frame assembly to have multiple connecting cavities, electrical busses can be included in the cavity to route the generated power out of the frame of the respective door, skylight, and/or wall to another electrical system which may either use the power directly or include it as a power input for a solar energy collection system.

In some implementations, each light collection panel includes a first optical layer (for example, a transmissive pane of glass or plastic) having a top surface and a bottom surface, the top surface including a plurality of micro-lenses that are configured to focus sunlight received by the panel. The light collection panel can also include a second optical layer (for example, a transmissive pane of glass or plastic) having a top surface and a bottom surface, the second optical layer disposed behind the first optical layer such that the bottom surface of the first optical layer is between the top surface of the first optical layer and the second optical layer and the top surface of the second optical layer is positioned to be facing the bottom surface of the first optical layer. The bottom surface of the second optical layer can include a plurality of light turning features that redirect incident light toward one or more edges of the second optical layer. The optical layers can be positioned relative to each other to include a gap between the first and second optical layer. To generate power from the light turned towards the edge of the optical layer, at least one photovoltaic cell is positioned along at least one edge of the second optical layer. In some implementations, wires are integrated into one or more of the turning features and these wires may be used to connect one PV panel to another PV panel, for example, an adjacent PV panel. In some implementations, the wires are integrated into a recess in the back side (opposite the direction of incoming incident light) of the turning feature such that the wires are barely or not at all visible when the PV panel is viewed from the side exposed to incident light.

Some implementations can include multiple PV cells and they can be positioned along one or all of the edges of an optical layer. For example, photovoltaic cells can be positioned on opposite edges of the second optical layer of the collection panels. In some implementations, the energy collecting apparatus can further include a number of printed circuit boards (PCB) each PCB being coupled to the photovoltaic cells that are on one edge of the second optical layer of a collection panel. Each respective PCB is configured to electrically connect to the plurality of photovoltaic cells to connect the plurality of photovoltaic cells in serial and provide two electrical output terminals for outputting power generated by the plurality of photovoltaic cells coupled to the PCB. Some implementations also include integrated electronics and micro-inverters coupled to the printed circuit boards.

Particular implementations of the subject matter described in this disclosure can be implemented to realize one or more of the following potential advantages. The implementations described herein can be integrated in architectural structures including, for example, doors, windows, roofs, skylights, or walls to simultaneously generate PV power and provide natural lighting to the interior of the architectural structures. The frame assembly implementations described herein can be used to add strength to areas that may alternatively just include a glass pane. The configuration of the frame assembly to have a cavity to house wiring and other components adds to the clean design of the overall structure in which the frame assembly is used, and provides protection from the environment for electrical components including wiring within the frame. In addition, a metallic frame may help dissipate heat that may be caused by PV power generation.

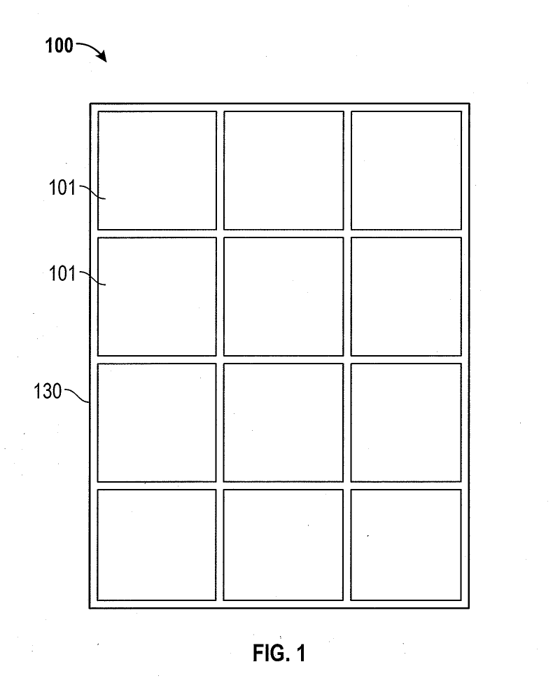

FIG. 1 is a plan view of a schematic illustrating one example of an implementation of a framed PV panel assembly 100. The framed PV panel assembly 100 may include multiple transmissive photovoltaic PV panels 101, for example, twelve (12) 1′×1′ transmissive PV panels 101 in a 3×4 configuration, as illustrated in FIG. 1. In some implementations, the framed PV panel 100 may include as few as two transmissive PV panels 101. In other implementations, the framed PV panel 100 may include three or more transmissive PV panels 101, for example, twelve or more PV panels 101. The framed PV panel 100 can be configured in a rectangular shape of n×n transmissive PV panels as illustrated in FIG. 1, or in a non-rectangular shape as desired for other implementations. A framed PV panel 100 (for example, the rectangular-shaped framed PV panel) can be incorporated into a door, a window, a skylight, a wall, a roof, or another structure of a commercial or residential building. The framed PV panel assembly 100 illustrated in FIG. 1 also includes a frame 130 configured to have multiple opening each of which can hold and support the transmissive PV panels 101. The frame 130 may be configured to surround at least a portion of the transmissive PV panels 101 of the framed PV panel assembly 100. As described in more detail with reference to FIG. 5, the frame 130 may be configured such that a portion of the frame coupled to the transmissive PV panels 101 includes a cavity which may house electrical busses and/or wiring and other electrical and electronic components that may be used to produce solar power.

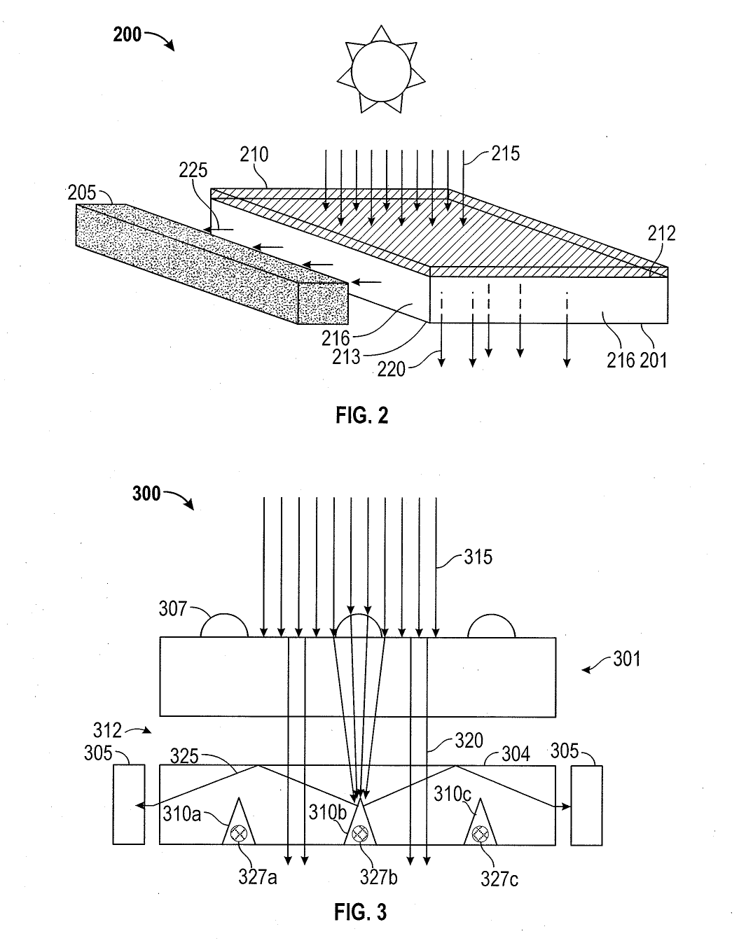

FIG. 2 is a schematic illustrating a perspective view of an example of an implementation of a transmissive PV panel 200 that includes a light guide 201 and at least one PV cell 205 that may be incorporated into a framed PV panel assembly, for example, as illustrated in FIG. 1. The light guide 201 includes a forward surface 212 that receives ambient light, represented by ray 215. The light guide 201 also includes a rearward surface 213, opposite the forward surface 212, through which a portion of the received ambient light is transmitted out of the light guide 201. A person having ordinary skill in the art will appreciate that the terms “forward” and “rearward” as used in referring to light collector surfaces herein do not indicate a particular absolute orientation, but instead are used to indicate a light collecting surface (“forward surface”) on which natural light is incident and a surface where a portion of the incident light received on the forward surface can propagate out from (“rearward surface”).

In FIG. 2, ray 220 is a representative of a portion of the received light that propagates out of the light guide 101 from the rearward surface 213. A plurality of edges 216 are enclosed between the forward and rearward surfaces 212 and 213 of the light guide 201. As illustrated in FIG. 2, a PV cell 205 is disposed with respect to one of the edges 216 of the light guide 101. Although, only one PV cell 205 is illustrated in FIG. 2, it is understood that additional PV cells can be disposed along one or more of the other edges 216 of the light guide 201. The light guide 201 illustrated in FIG. 2 includes a plurality of optical features 210 that are configured to divert or turn a first portion of the incident ambient light towards the PV cell 205.

In FIG. 2, ray 225 is a representative of a diverted portion of light which propagates through the light guide 201 by successive total internal reflections on the forward and the rearward surfaces towards the PV cell 205. In various implementations, the light guide 201 can include a transparent or transmissive material such as glass, plastic, polycarbonate, polyester or cyclo-olefin. In various implementations, the forward and rearward surfaces 212 and 213 of the light guide 201 can be parallel. In other implementations, the light guide 201 can be wedge shaped such that the forward and rearward surfaces are inclined with respect to each other. The light guide 201 may be formed as a plate, sheet or film, and fabricated from a rigid or a semi-rigid material. In various implementations, portions of the light guide 201 may be formed from a flexible material.

In various implementations, the plurality of optical features 210 may be disposed on the forward or rearward surfaces 212 and 213 of the light guide 201. The plurality of optical features can include optical refractive, reflective or diffractive features. In some implementations, the light guide 201 can include a substrate and a film or a plate provided with the plurality of optical features 210 can be adhered or attached to the substrate. In various implementations, the plurality of optical features 210 can be manufactured using methods such as etching, embossing, imprinting, lithography, etc. The plurality of optical features 210 can include white paint that is applied to the forward or rearward surfaces 212 and 213 of the light guide 201.

An implementation similar to the transmissive PV panel 200 illustrated in FIG. 2 can be used as a BIPV product (for example, window, skylight, façade, glazing, curtain wall, etc.). A BIPV product using a transmissive PV panel 200 or other implementations of a light collector as described herein can reduce the cost of the BIPV product since the PV cells are used only at the edges of the light guide (for example, light guide 201). High efficiency Si or solar cells can be used in various implementations to increase the photoelectric conversion efficiency. A BIPV product using a transmissive PV panel 200 or other implementations of a light collector as described herein can additionally reduce color dispersion and image distortion; serve as thermal barrier and block solar radiation thereby aid in reducing heating and cooling costs; be designed to meet advanced building codes and standards; minimize fire hazard; supply better daylight as compared to conventional BIPV products; recycle indoor lighting energy; help in achieving “net zero building” by generating electric power, be cut into arbitrary shapes and sizes according to the building requirement; be compatible with curved glass windows and be aesthetically pleasing as conventional windows. Additionally, a BIPV product using a light collector 200 or other implementations of a light collector as described herein can be a good candidate for use as windows, privacy screens, skylights, etc. since the amount of light transmitted can be varied or controlled by varying or controlling a density or fill factor of the plurality of optical features.

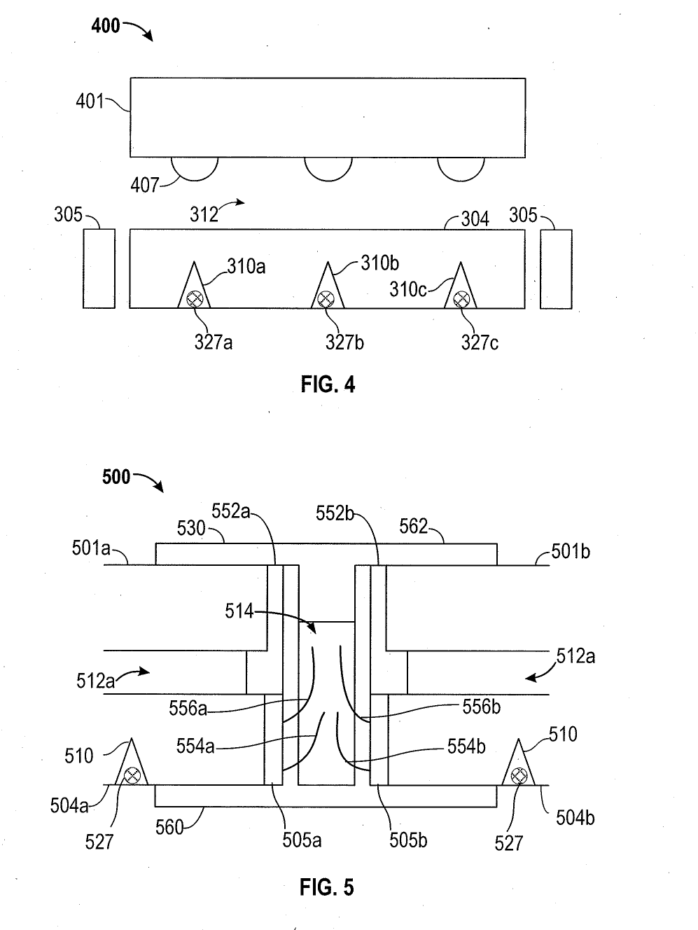

FIG. 3 is a schematic illustrating a side view of another example of an implementation of a transmissive PV panel that can be incorporated into a framed panel assembly, for example, as illustrated in FIG. 1. FIG. 4 is a schematic illustrating a side view of another example of an implementation of a transmissive PV panel that can be incorporated into a framed panel assembly, for example, as illustrated in FIG. 1.

The examples shown in FIGS. 3 and 4 illustrate PV panels having micro-lenses and multi-cone light redirecting structures (which may also be referred to as “turning features”) that can be configured as solar power generating windows. The implementations of the transmissive PV panels 300 (FIG. 3) and 400 (FIG. 4) include a two-piece structure. In FIG. 3, the first piece of the structure is a micro-lens array 301 that includes a plurality of micro-lenses 307. In FIG. 4, the first piece of the structure is a micro-lens array 401 that includes a plurality of micro-lenses 407. In both FIGS. 3 and 4, the second piece of the PV panel is a light guide 304 that includes a plurality of turning features 310 that can direct light towards one or more PV cells 305 disposed along one or more edges of the light guide 304. The light collector 300 can also include other structures which provide structural support or change an optical characteristic (for example, a filter). Where appropriate, structures and features of light guide 201 (FIG. 2) discussed herein may be incorporated into light guide 304. For example, light guide 304 may be made of the same or similar materials as those discussed for light guide 201. As another example, the plurality of optical features 310 can be fabricated using methods similar to the fabrication of the plurality of optical features 210.

The PV cells 305 can convert light into electrical power. In various implementations, the PV cell 305 can include solar cells. The PV cell 305 can include a single or a multiple layer p-n junction and may be formed of silicon, amorphous silicon or other semiconductor materials such as Cadmium telluride. In some implementations, the PV cell 305 can include photo-electrochemical cells. Polymer or nanotechnology may be used to fabricate the PV cell 305. In various implementations, the PV cell 305 can include multispectrum layers, each multispectrum layer having a thickness between approximately 1 μm to approximately 250 μM. The multispectrum layers can further include nanocrystals dispersed in polymers. Several multispectrum layers can be stacked to increase efficiency of the PV cell 305.

The transmissive PV panels 300 illustrated in FIG. 3 includes a gap 312 between the micro-lens array 301 and the light guide 304. The transmissive PV panels 400 illustrated in FIG. 4 also includes a gap 312 between the micro-lens array 401 and the light guide 304. In various implementations, the gap 312 can include a layer of material (e.g., a gas, air, nitrogen, argon, a solid material, or a viscous material) having a refractive index lower than the refractive index of the material of the light guide 304. In other implementations, the gap 312 can be wholly or partially devoid of material or substance and can be a vacuum.

In various implementations, the micro-lens arrays 301 and 401 and/or the light guide 304 may be formed as a plate, sheet or film. In various implementations, the micro-lens arrays 301 and 401, and/or the light guide 304 may be fabricated from a rigid or a semi-rigid material or a flexible material. In various implementations, the micro-lens arrays 301 and 401, and the light guide 304 can have a thickness of approximately 1-10 mm. In various implementations, the overall thickness of the transmissive PV panels 300 and 400 can be less than approximately 4-8 inches.

In FIG. 3, the micro-lens array 301 includes a substrate having a forward surface that receives incident light and a rearward surface through which light is transmitted out of the micro-lens array 301. In various implementations, the plurality of micro-lenses 307 can be disposed on the forward surface of the substrate as shown in FIG. 3. As illustrated in FIG. 4, in various implementations the plurality of micro-lenses 407 can be disposed on the rearward surface of the micro-lens array 401, that is, the surface of the micro-lens array 401 opposite of the surface that is exposed and first receives incident light (or radiation). In some implementations, a film, a layer or a plate that includes the plurality of micro-lenses 307 and 407 can be adhered, attached or laminated to the forward or rearward surface of the micro-lens array 301 and 401. In various other implementations, the plurality of micro-lenses can be disposed through-out the volume of the micro-lens array. In some implementations, some or all of the plurality of micro-lenses 307 and 407 can include a hemispherical structure. In some implementations, some or all of the plurality of micro-lenses 307 and 407 can have parabolic or elliptical surfaces, and/or can include semi-cylindrical structures. In various implementations, each of the plurality of micro-lenses 307 and 407 can have a diameter of approximately 0.1-8 mm. In some implementations, the distance between adjacent micro-lenses 307 and 407 (pitch) in the micro-lens array 301 can be between approximately 1 mm and approximately 5 cm. The plurality of micro-lenses 307 and 407 may be formed by a variety of methods and processes, including lithography, etching, and embossing.

For window based building integrated photovoltaic (BIPV) products, wiring management from the solar cells to the junction box is an important design consideration. There are two consideration of primary importance: (1) minimum electrical resistance added to the circuits, and (2) least blockage of the Sun light to the active solar cell surfaces. Both considerations are for maximizing the energy conversion efficiency of the system. For conventional thin film based BIPV products, the two considerations are usually addressed with optically transparent thin film materials such as Indium Tin oxide (ITO), Tin oxide (SnO2), etc. that are part of the cell design. While such thin films are transparent to human eyes, they absorb strongly in UV and have inferior conductivity compared with metal. For crystalline Si based window type BIPV products metallic wire is the primary choice for the circuit connection. In order to avoid blocking of the sunlight and best aesthetic appeal, wires usually travel along the (inner) edges and corners of a BIPV unit. The downside for such arrangement will be the ohmic power loss due to the extra length of the wire. As a new technology for BIPV products, SoLux based windows, usually in IGU (insulated glass unit) form, also benefit from invisible electrical connections between the solar cells along the light collecting path while the energy loss due to wire resistance is minimized.

To address these considerations, conducting materials (for example, wires, electrical busses) can be disposed behind the turning features and used for electrical conduction and heat transfer. Such conductive materials may be referred to as turning feature integrated wires (“TFI wires”). As illustrated in FIGS. 3 and 4, the turning features 310a-c (collectively or generically referred to as turning features 310) each include TFI wires 327a-c (collectively or generically referred to as TFI wires 327). In some implementations, one or more of the turning features 310 include TFI wires 327. In some implementations, all of the turning features 310 include TFI wires 327. In some implementations, electrically and thermally conducting materials (for example, metallic wires) having a cross-section sized to that of the turning feature (for example, having a cross-section area smaller than the turning feature) are laid along and inside the trench of the turning feature 310 across the aperture of the unit. In some implementations, the TFI wires 327 are actual wires disposed in the turning features 310. In some implementations, the TFI wires 327 include one or more conductive materials placed into the turning features 310 such that they form a conductive bus.

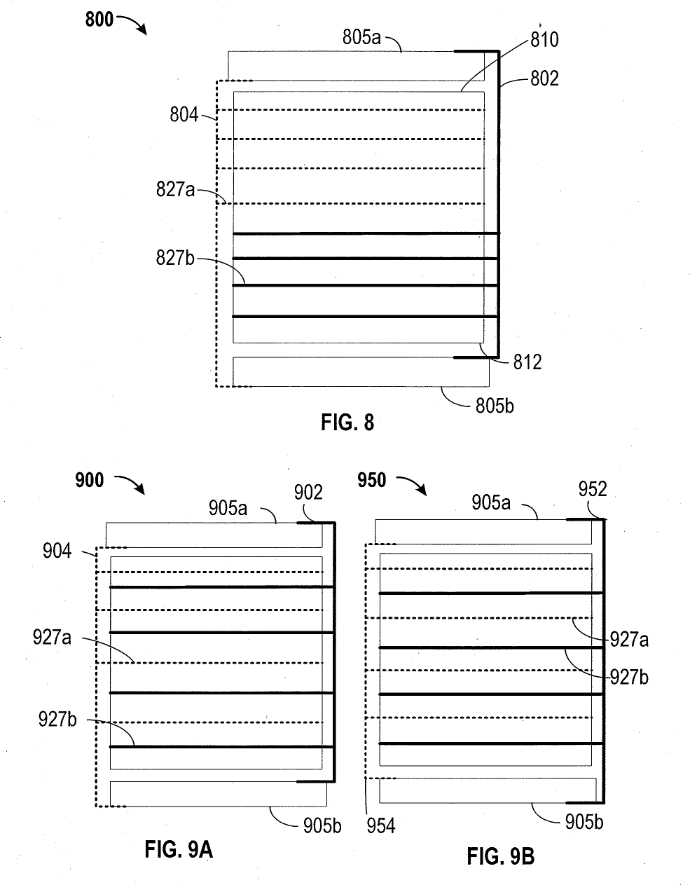

In implementations where the light guide 304 and turning features 310 are made of dielectric material and the metallic reflective coating on the turning facets are not otherwise electrically connected to the circuit, the TFI wires 327 can be either insulated or non-insulated without detrimentally affecting optical characteristics of the light guide 304. For electrical energy transfer, the TFI wires 327 can be part of the electric circuit connecting the solar cells and transmitting the electricity to the external receiving devices. Some example implementations of using TFI wires 327 are illustrated in FIGS. 8, 9 and 10A and 10B. For heat transfer, the added thermal mass, conduction cross section, and surface area already improve the heat dissipation away from the solar cell chips. Further heat transfer enhancement can be realized by implementing advanced heat transfer technology such as heat pump to the TFI wires. TFI wires 327 integrated into the turning features 310 have minimal or no light blockage to the solar cells due to the wires. Other advantages of incorporating TFI wires 327 into the light guide 304 may include better protection of the reflective coating/surface, and improved heat dissipation of the reflecting surface of the turning features.

In some implementations, the micro-lens arrays 301 and 401, and the light guide 304 can include a material that is transmissive to visible light, for example, inorganic glass (e.g., crown, flint, float, eagle or borosilicate glass), organic or plastic glass (e.g., acrylic, polycarbonate, PMMA, etc.) or a composite glass including both organic and inorganic glass. The term “inorganic glass” as used here refers to an amorphous, inorganic, transparent, translucent or opaque material that is traditionally formed by fusion of sources of silica with a flux, such as an alkali-metal carbonate, boron oxide, etc. and a stabilizer, into a mass. This mass is cooled to a rigid condition without crystallization in the case of transparent or liquid-phase separated glass or with controlled crystallization in the case of glass-ceramics. The term “organic glass” as used here refers to the technical name for transparent solid materials made from such organic polymers as polyacrylates, polystyrene, and polycarbonates and from the copolymers of vinyl chloride with methyl methacrylate. The term “organic glass” will be understood by someone of ordinary skill in the art to indicate a sheet material produced by the block polymerization of methyl methacrylate.

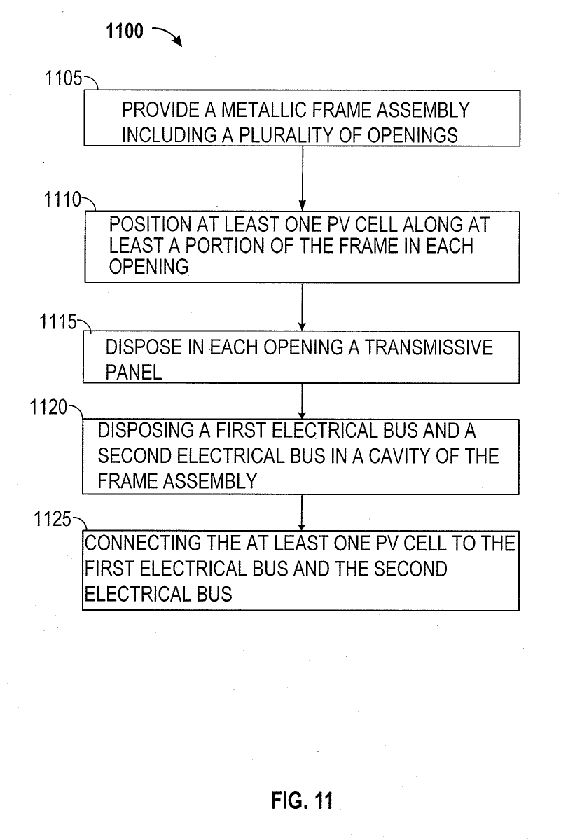

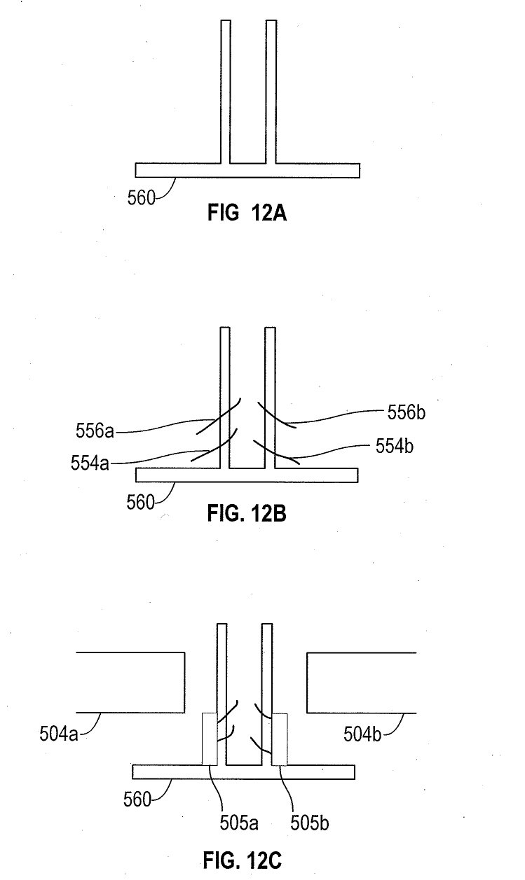

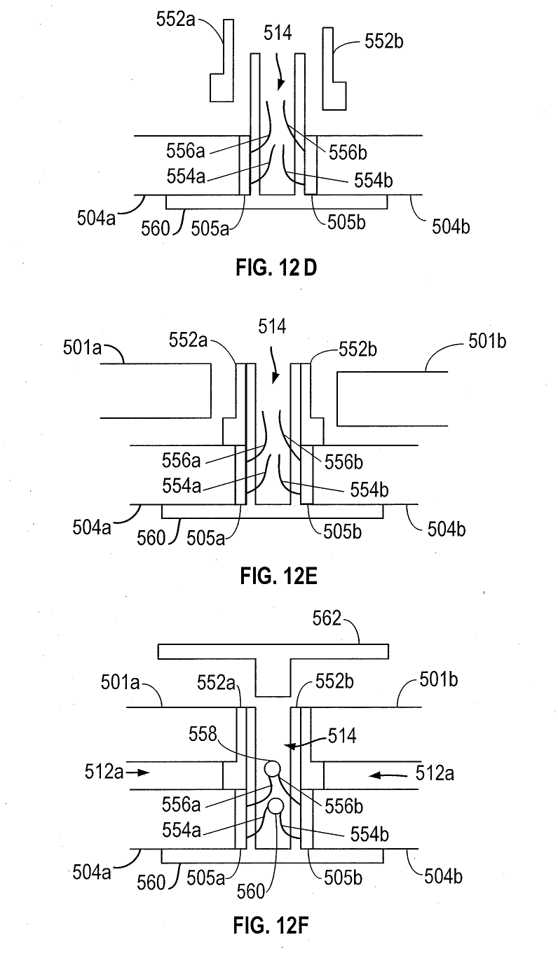

FIG. 5 is a schematic illustrating a side view of a portion of an example of an implementation of a framed panel assembly 500, showing portions of two transmissive PV panels and a frame holding the transmissive PV panels. The implementation illustrated in FIG. 5 will be further described after describing an implementation of portions of the framed panel assembly 500 being assembled, as illustrated in FIGS. 11 and 12A-12F.

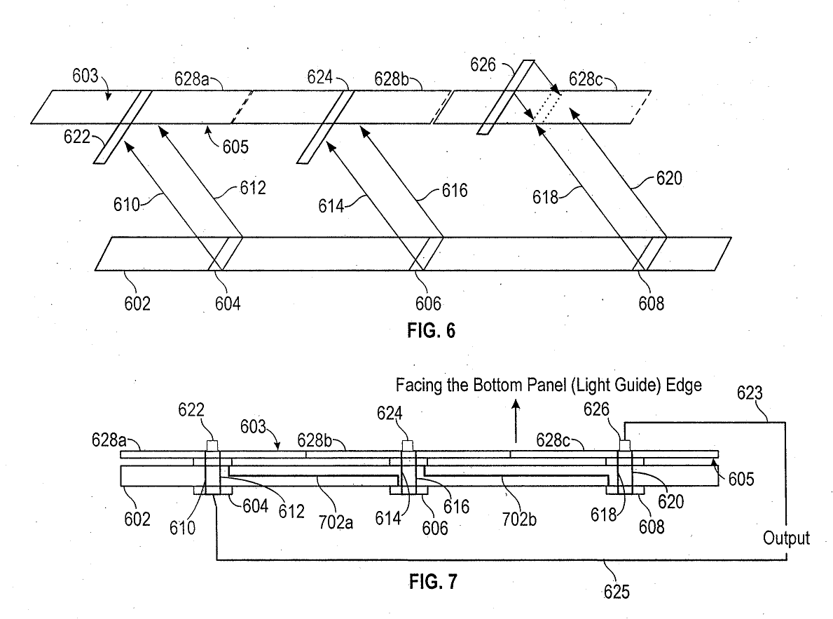

In some implementations, PV cells can be disposed on printed circuit boards and connected together in parallel or series, as desired, using conductive traces and vias of the PCBs. FIG. 6 is a schematic illustrating a perspective view of an example of an implementation of electrical connections between PV cells and electrical contacts on a printed circuit board (PCB). FIG. 7 is a schematic illustrating a side view of an example of an implementation of electrical connections between PV cells and electrical contacts on a printed circuit board. The configuration of PV cells 628a-c (collectively or generically referred to as PV cells 628) on a PCB 602 can be used in a framed PV panel assembly, for example, as illustrated in FIG. 5. As illustrated in FIGS. 6 and 7, electrical busses 622, 624 and 626 are connected to a first side 603 of one of PV cells 628 to carry power generated by the PV cells 628. As illustrated in FIGS. 6 and 7, the first side 603 is the side of PV cells 628 that are disposed facing the light guide (for example, light guides 504 of FIG. 5). A PCB 602 is disposed on the along a second side 605 of the PV cells 628. The PCB 602 includes soldering pads 604, 606 and 608 (electrical connections). The electrical bus 622 may be electrically connected to soldering pad 604 by electrical connections 610 and 612. Similarly, electrical bus 624 may be electrically connected to soldering pad 606 by electrical connections 614 and 616, and electrical bus 626 may be electrically connected to soldering pad 608 by electrical connections 618 and 620.

As illustrated in FIG. 7, conductive trace/vias 702a, along with electrical connections 614 and 616, and soldering pad 604b, connects the second side 605 of PV cell 628a to the first side 603 of PV cell 628b. Conductive trace/vias 702b, along with electrical connections 618 and 620, and soldering pad 604c, connect the second side of PV cell 628b to the first side of PV cell 628c. In this implementation, electrical power is output from the series connected PV cells 628 by electrical bus 623 which is connected to electrical bus 626 of PV cell 628c, and by electrical bus 625 which is connected to electrical bus 622.

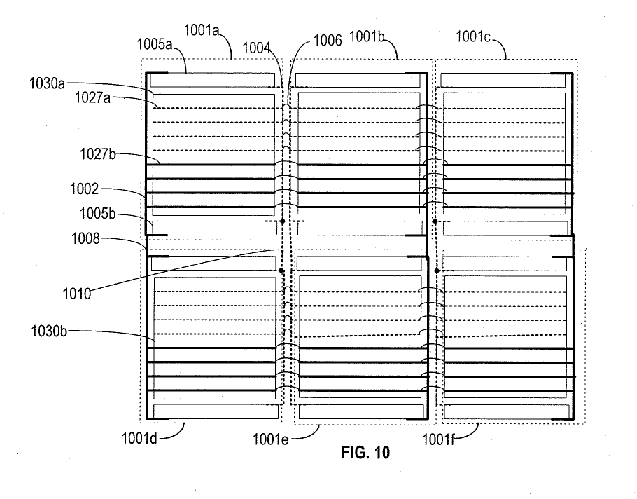

FIG. 8 is a schematic illustrating an example implementation of a transmissive PV panel 800 including a configuration of electrical wires that are integrated into turning features of the transmissive PV panel. In some implementations FIG. 8 may be a view of the backside of the PV panel 800. PV panel 800 may be configured with one or more other PV panels (for example, in multiple PV panel configuration similar to a configuration illustrated in FIG. 10). In the implementation illustrated in FIG. 8, the PV cells 805a and 805b are arranged such that they are electrically connected in series. The PV panel 800 includes a first PV cell 805a disposed along a first edge of the light guide/turning feature elements 810, which is also along a first edge of the PV panel 800 (that is, the top edge of the light guide/turning feature elements 810 relative to the page orientation of FIG. 8). The PV panel 800 also includes a second PV cell 805b disposed along a second edge 812 of the light guide/turning feature elements 810 (that is, the bottom edge of the light guide/turning feature elements 810, relative to the page orientation of FIG. 8) which is also along a second edge of the PV panel 800. In this implementation, the first PV cell 805a and the second PV cell 805b are in an electrical series configuration.

Specifically, in the implementation illustrated in FIG. 8, electrical bus 802 connects to a positive (+) electrical connection on the back of the first PV cell 805a and a negative (−) electrical connection on the front of the second PV cell 805b. Electrical bus 804 connects to a negative (−) electrical connection on the front of the first PV cell 805a and a positive (+) electrical connection on the back of the second PV cell 805b. TFI wires 827a, integrated into turning features of the PV panel 800 (that are disposed in a horizontal direction relative to FIG. 8 orientation) and disposed on the side of the PV panel 800 near the first PV cell 805a, are connected to electrical bus 804. TFI wires 827b, integrated into turning features of the PV panel 800 (that are disposed in a horizontal direction relative to FIG. 8 orientation) and disposed on the side of the PV panel 800 near the second PV cell 805a, are connected to electrical bus 802. The TFI wires 827a and 827b and the electrical busses 802 and 804 may be used to electrically connect PV panel 800 to other PV panels, for example, other PV panels disposed with PV panel 800 in a framed PV panel assembly.

FIG. 9A is a schematic illustrating a plan of an example implementation of a transmissive PV panel 900 showing solar cells of a transmissive PV panel connected in series. FIG. 9B is a schematic illustrating a plan view of the rear of an example implementation of a transmissive PV panel 900 showing solar cells of a transmissive PV panel connected in parallel. In some implementations, FIGS. 9A and 9B may be views of the backside of the PV panels 900 and 950, respectively.

The configuration of PV panel 900 includes PV cells 905a and 905b disposed along the top and bottom edge of the PV panel 900, respectively (relative to the orientation illustrated in FIG. 9A), which is also along an edge of light guide/turning feature elements 910. PV panel 950 includes PV cells 905a and 905b disposed along the top and bottom edge of the PV panel 950, respectively (relative to the orientation illustrated in FIG. 9B), which is also along an edge of light guide/turning feature elements 910. The PV panels 900 and 950 include TFI wires 927a and 927b. The PV panels 900 and 950 also each include two electrical busses 902 and 904, and 952 and 954, respectively. In FIG. 9A, the TFI wires 927a are connected to electrical bus 904, and TFI wires 927b are connected to electrical bus 902. In FIG. 9B, the TFI wires 927a are connected to electrical bus 954, and TFI wires 927b are connected to electrical bus 952. In these two implementations, the TFI wires 927a and 927b are disposed in parallel and such that they alternate in order across the PV panel. In other words, moving from the first PV cells 905a across the PV panels 900 and 950 towards the second PV cells 905b, the TFI wires 927a and 927b are positioned in alternating order, for example, a first TFI wire 927a, a first TFI wire 927b, a second TFI wire 927, a second TFI wire 927b, etc. Such a configuration may be referred to as symmetrical configuration of TFI wires.

The PV cells 905a and 905b of PV panel 900 (FIG. 9A) are electrically connected in series. Specifically, electrical bus 902 is electrically connected to a back positive (+) connection of PV cell 905a, and is also electrically connected to a front negative (−) connection of PV cell 905b. Electrical bus 904 is electrically connected to a back positive (+) connection of PV cell 905b, and is also electrically connected to a front negative (−) connection of PV cell 905a. The PV cells 905a and 905b of PV panel 950 (FIG. 9B) are electrically connected in parallel. Specifically, electrical bus 952 is electrically connected to a back positive (+) connection of PV cell 905a and electrically connected to a back positive (+) connection of PV cell 905b. Electrical bus 954 is electrically connected to a front negative (−) connection of PV cell 905a and is also electrically connected to a front negative (−) connection of PV cell 905b. Symmetrical configuration implementations of the TFI wires (for example, as illustrated in FIGS. 9A and 9B) may provide the lowest resistance from the PV cells to external power receiving devices, in addition to other advantages described above.

FIG. 10 is a schematic illustrating an example of an implementation of parallel electrical connections between six transmissive PV panels 1001a-f (collectively or generically referred to as PV panels 1001). The illustrated view may be the back (rear) of the PV panels 1001 illustrates certain electrical connections and configurations. In such implementations, at least some of the electrical connections form a parallel circuit using turning feature integrated wires (“TFI wire”). The TFI wire may be used as the electrical bussing or wire that is integrated into one or more turning features of a transmissive PV panel and provide multiple electrical connections when connecting to other transmissive PV panels. The TFI wire is further described herein, for example, in reference to FIGS. 3 and 4.

In FIG. 10, the six PV panels 1001 are arranged in a 2 row×3 column configuration. For clarity of FIG. 10, features of all of the transmissive PV panels 1010 are not enumerated, instead the features of PV panel 1001a are numbered and specifically described, with the understanding that the other PV panels 1001b-f have like features, as illustrated. Each PV panel 1001 includes light guide/turning feature elements 1030a (also illustrated for PV panel 1001d as light guide/turning feature elements 1030b), which may be the light guide and turning feature elements as illustrated and described with reference to FIGS. 2, 3 and 4. In some implementations and as illustrated here, within each of the PV panels 1001, the two PV cells of the panel may be electrically connected in parallel. For example, PV panel 1001a includes a first PV cell 1005a disposed along a first edge of the PV panel 1001a (a top edge of the PV panel 1001a in the orientation illustrated in FIG. 10) and a second PV cell 1005b disposed along a second edge of the PV panel 1001a (a bottom edge of the PV panel 1001a in the orientation illustrated in FIG. 10). PV panel 1001a also includes an electrical bus 1002 connected to a positive (+) electrical connection of the PV cells 1005a and 1005b, illustrated in FIG. 10 as being connected to the back side of the PV cell 1005a and 1005b, that is, the side of the PV cell facing away from the PV panel 1001a. The electrical bus 1002 is also connected to one or more (here shown as four) TFI wires 1027b that are arranged across the PV panel 1001a (“across” being illustrated in a horizontal direction in reference to the FIG. 10 orientation). The electrical bus 1002 is also electrically connected, by an electrical connector 1008, to a similarly connected electrical bus of PV panel 1001d, which is also connected to one or more TFI wires disposed in PV panel 1001d, such that PV panels 1001a and 1001d are in an electrical parallel configuration.

PV panel 1001a further includes an electrical bus 1004 that is electrically connected a negative connection of PV cell 1005a and a negative connection of PV cell 1005b, illustrated in FIG. 10 as being connected to the front side of the PV cell 1005a and 1005b, that is, the side of the PV cell facing towards the PV panel 1001a. The electrical bus 1002 may also connect to one or more (here shown as four) TFI wires 1027a that are arranged across the PV panel 1001a (“across” illustrated in a horizontal direction in reference to the FIG. 10 orientation). The electrical bus 1002 is also electrically connected, by an electrical connector 1010, to a similarly connected electrical bus of PV panel 1001d, which is also connected to one or more TFI wires disposed in PV panel 1001d, such that PV panels 1001a and 1001d may be in an electrical parallel configuration. One or more of the TFI wires 1027a and 1027b of PV panel 1001a may be electrically connected to TFI wires on adjacent PV panel 1001b by electrical connectors 1006. As illustrated in FIG. 10, in a similar manner as described for panels 1001a, 1001b, and 1001d, all six of the PV panels 1001a-f can be connected together using, for example, connections similar to the TFI wires 1027, electrical busses 1002 and 1004, electrical connector 1008, 1010 and 1006, such that the PV cells of all six PV panels 1001a-f are electrically connected in parallel. An advantage of such a parallel configuration is that power output electrical connections (not shown) can be from one or more of a number of locations, for example, from the electrical busses 1002 and 1004. Using TFI wires and other connectors, the PV panels can also be configured in a series electrical connection, or a partial series and partial parallel connection.

FIG. 11 is a flow chart illustrating an example of a method 1100 of manufacturing an implementation of a large area photovoltaic energy collecting window having a frame assembly and multiple light collection panels. The flow chart is described referencing schematics in FIGS. 12A-12F. FIGS. 12A-12F are schematics illustrating cross-sectional views of portions of a frame assembly and PV transmissive panels during certain stages of manufacturing. In FIG. 11, the method 1100 at block 1105 provides a metallic frame assembly including a plurality of openings. In some implementations, such a frame assembly can be the frame assembly 100 described in FIG. 1. FIG. 5 also illustrates certain features of such a frame assembly 530. FIG. 12A illustrates a frame base of a frame assembly 530 that can be provided at block 1105. In the method 1100, block 1110, at least one PV cell is positioned along at least a portion of the frame in each opening. FIGS. 12B and 12C illustrate, for a first PV cell 505a, electrical connections 554a and 556a that are routed through a portion of the frame 560, and for a second PV cell 505b, electrical connections 554b and 556b that also go through a portion of the frame 560. The electrical connections 554 and 556 may, for example, pass through openings apertures formed in the frame 560. In some implementations, the electrical connections 554 and 556 are connected to electrical connectors disposed in the frame that provide a conductive path through the frame 560 that can be further connected to an electrical bus or a wire inside a cavity of the frame.

At block 1115, a transmissive panel may be disposed in each of the openings in the frame. FIGS. 12C, 12D and 12E illustrate disposing a transmissive panel in the frame 560. In this implementation, the transmissive panel includes a micro-lens array 501 and a light guide 504. As illustrated in FIG. 12D, each light guide 504 may be disposed such that an edge of the light guide 504 is positioned against, or near, a PV cell 505 so that at least a portion of light propagating in the light guide 504 can exit the light guide 504 and be incident on the PV cell 505. Spacers 552 can be disposed on the light guide 504 to support a micro-lens array 501, spacing a micro-lens array 501 apart from the light guide 504 and forming a cavity 512 (shown in FIG. 12F) between the micro-lens array 501 and the light guide 504.

At block 1120, a first and second electrical bus are disposed in a cavity of the frame. FIG. 12F illustrates a first electrical bus 558 and a second electrical bus 560 positioned within the cavity 512a of the frame 560. At block 1125, PV cell 505a is connected to the first electrical bus 558 and the second electrical bus. Electrical connections 554a from PV cell 505a and 554b from PV cell 505b are connected to the electrical bus 560. Electrical connections 556a from PV cell 505a and 556b from PV cell 505b are connected to the electrical bus 558. Other PV cells (not shown) can also be connected to the electrical busses 558 and 560. In the illustrated implementation, the PV cells 505a and 505b are electrically connected in parallel. In other implementations, the PV cells can be electrically connected in series, or a combination of series and parallel. FIG. 12f also illustrates that a frame cap 562 can be coupled to the other portion of the frame 560 to enclose the cavity 512a.

Referring again to FIG. 5, FIG. 5 illustrates a side view of a portion of an example of an assembled implementation of a framed panel assembly 500, showing portions of two transmissive PV panels and a frame holding the transmissive PV panels. The transmissive PV panels illustrated in FIG. 5 are examples of PV panels used in some implementations, others can also be used (for example, as illustrated in FIGS. 3 and 4). As illustrated in the example implementation of FIG. 5, a first PV panel includes a micro-lens array 501a and a light guide 504a. The framed panel assembly 500 also includes an I-beamed shaped frame 530 that includes a frame base 560 and a frame cap 562, shown coupled together. The frame 530 can include metal. The micro-lens array 501a and the light guide 504a are disposed relative to each other such that there is a gap 512a therebetween. A second PV panel includes a micro-lens array 501b and a light guide 504b, and are also disposed to have a gap 512b between the micro-lens array 501b and the light guide 504b. The light guides 504a and 504b include one or more light turning features 510. One or more of the turning features 510 may include TFI wires 527.

As illustrated in FIG. 5, in this implementation spacers 552a and 552b are disposed between the micro-lens arrays 501a and the light guide 504a, and between the micro-lens array 501b and the light guide 504b, respectively, to form the gaps 512. In this implementation, a portion of the spacers 552 is disposed along the frame base 560 between the micro-lens arrays 501 and the frame base 560 to provide support of the edge of the micro-lens array 501a disposed proximate to the frame 530. The gaps 512 can be filled with air or another gas, or can be devoid of gas and instead be a vacuum. The frame 530 having the cavity 514 provides advantages of lower weight than a solid frame, as well as having a protected duct to house wires connected to the PV cells. In addition, the frame 530 can provide enhanced dissipation of heat generated by solar energy production due to its thermal characteristics and the increased surface area of the “hollow” I-beam shaped frame 530.

The framed panel assembly 500 also includes PV cells 205a and 205b, which are each disposed along a portion of the frame and along an edge of the light guides 504a and 504b, respectively, such that light that exits the light guides 540a and 504b along the edges proximate to the PV cells 205a and 205b (illustrated in FIG. 2) is incident on the PV cells. Electrical connections 554a and 556a connected to PV cell 205a pass through apertures (not shown) in the frame base 560 and into a cavity 514. Electrical connections 554b and 556b connected to PV cell 205b pass through apertures (not shown) in the frame base 560 and into the cavity 514. In the cavity 514, the electrical connections 554 and 556 can connect the PV cells 205 in serial or in parallel, and can also connect to other PV cells of the framed panel assembly 500 in parallel or series electrical connections. The frame 530 includes the cavity 514 within the frame base 560. The cavity 514 may house electrical busses (for example, wiring) connecting PV cells together and other electrical components or mechanical components.

The above-described implementations and other similar implementations can be used as a (building-integrated photovoltaic) BIPV product (for example, window, skylight, façade, door, glazing, or a curtain wall). A BIPV product using a device similar to those described herein can reduce the cost of the BIPV product since the PV cells are used only at the edges of the device (for example, first optical structure 101 or the light guide 107). High efficiency Si or III-V solar cells can be used in various implementations to increase the photoelectric conversion efficiency. A BIPV product using a device similar to those described herein can additionally reduce color dispersion and image distortion; serve as thermal barrier and block solar radiation thereby aid in reducing heating and cooling costs; be designed to meet advanced building codes and standards; minimize fire hazard; supply better daylight as compared to conventional BIPV products; recycle indoor lighting energy; help in achieving “net zero building” by generating electric power, be cut into arbitrary shapes and sizes according to the building requirement; be compatible with curved glass windows and be aesthetically pleasing as conventional windows. Additionally, a BIPV product using a device similar to those described herein can be used for windows, privacy screens, skylights, etc. A BIPV product using a device similar to those described herein can be used to generate PV power efficiently at various times during the day and also provide natural and/or artificial lighting.

Various implementations of the devices described herein can be used to efficiently generate PV power and provide artificial lighting. The devices described herein can be relatively inexpensive, thin and lightweight. The devices described herein including light collectors and light guides with focusing elements and light redirecting elements and coupled to one or more PV cells and one or more illumination sources can be used in a variety of applications. For example, various implementations of devices described herein can be configured as building-integrated photovoltaic products such as, for example, windows, roofs, skylights, facades, etc. to generate PV power and provide artificial lighting. In other applications, various implementations of devices described herein may be mounted on automobiles and laptops to provide PV power and artificial light. Various implementations of the devices described herein can be mounted on various transportation vehicles, such as aircrafts, trucks, trains, bicycles, boats, etc.

Implementations discussed herein may include light guides, focusing elements, and light turning (or redirecting) features that provide an optical path for incident light to reach one or more PV cells in a PV panel or PV framed assembly. Accordingly, PV cells may have an advantage if they are modular, at least somewhat separate from other optical components for maintenance and upgrade purposes. For example, depending on the design, the PV cells may be configured to be removably attached. Thus existing PV cells can be replaced periodically with newer and more efficient PV cells without having to replace the entire system. This ability to replace PV cells may reduce the cost of maintenance and upgrades substantially.

A wide variety of other variations are also possible, in addition the implementations described above. Films, layers, components, and/or elements may be added, removed, or rearranged in the described implementations. Additionally, processing operations may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A photovoltaic energy collecting apparatus, comprising:
a plurality of transmissive light collection panels, each of the light collection panels including at least one photovoltaic cell disposed along an edge of the light collection panel, each of the plurality of light collection panels configured to pass through a first portion of received incident light and use a second portion of received incident light to generate photovoltaic energy;
a first electrical output terminal and a second electrical output terminal;
a first electrical bus and a second electrical bus; and
a metallic frame assembly including a plurality of openings, each of the plurality of light collection panels being disposed in one of the openings of the frame assembly such that the frame assembly surrounds and supports each light collection panel,
wherein a portion of the frame assembly that surrounds each of the plurality of light collection panels includes a cavity that houses the first electrical bus and the second electrical bus, the first electrical bus being electrically connected to each of the at least one photovoltaic cells and to the first electrical output terminal, and the second electrical bus being electrically connected to each of the at least one photovoltaic cells and to the second electrical output terminal.

2. The apparatus of claim 1, wherein each light collection panel includes
a first optical layer having a top surface and a bottom surface, the top surface including a plurality of micro-lenses configured to focus incident sunlight received thereon;
a second optical layer having a top surface and a bottom surface, the second optical layer disposed behind the first optical layer such that the bottom surface of the first optical layer is between the top surface of the first optical layer and the second optical layer and the top surface of the second optical layer is disposed facing the bottom surface of the first optical layer, the bottom surface of the second optical layer including a plurality of light turning features configured to redirect light incident thereon toward one or more edges of the second optical layer; and
a gap between the first optical layer and the second optical layer,
wherein the at least one photovoltaic cell is disposed along at least one edge of the second optical layer.

3. The apparatus of claim 1, wherein the at least one photovoltaic cell includes at least one photovoltaic cell disposed on each of two opposite edges of the plurality of light collection panels.

4. The apparatus of claim 2, wherein the at least one photovoltaic cell includes at least one photovoltaic cell disposed on each of two opposite edges of the second optical layer.

5. The apparatus of claim 2, wherein the at least one photovoltaic cell includes a plurality of photovoltaic cells disposed on opposite edges of the second optical layer of the collection panels, and wherein the apparatus further comprises a plurality of printed circuit boards (PCB) each coupled to the plurality of photovoltaic cells disposed on one edge of the second optical layer of a collection panel, wherein each respective PCB is configured to electrically coupled to the plurality of photovoltaic cells to connect the plurality of photovoltaic cells in serial and provide two electrical output terminals for outputting power generated by the plurality of photovoltaic cells coupled to the PCB.

6. The apparatus of claim 5, further comprising integrated electronics and micro-inverters coupled to the printed circuit boards.

7. The apparatus of claim 3, wherein the frame assembly includes spacers disposed between the each light collection panel first and second optical layers such that there is a gap therebetween.

8. The apparatus of claim 6, wherein the frame assembly comprises a plurality of I-frame shaped members, wherein the center of the I-frame shaped members includes the cavity, and wherein the top and bottom of the I-frame support the light collection panels.

9. The apparatus of claim 8, wherein the first electrical bus and the second electrical bus are disposed in the cavity and connect to the first and second electrical terminals in the cavity, and wherein the first and second electrical terminals provide an electrical connection through the frame assembly.

10. The apparatus of claim 8, wherein a portion of the frame assembly around each collection panel includes at least one aperture, and wherein the first and second terminals pass through the at least one aperture of the frame assembly and connect to the first electrical bus and the second electrical bus in the cavity.

11. The apparatus of claim 8, wherein a portion of the frame assembly around each collection panel includes two electrical connectors, and wherein the first and second terminals are electrically connected to the first electrical bus and the second electrical bus, respectively, by the two electrical connectors.

12. The apparatus of claim 2, further comprising one or more turning feature integrated (TFI) wires disposed in the turning features of a first light collection panel, the one or more TFI wires electrically connected to one of the first electrical bus and the second electrical bus.

13. The apparatus of claim 12, further comprising one or more TFI wires disposed in turning features of a second light collection panel, the TFI wires of the first light collection panel being electrically connected to TFI wires in the second light collection panel.

14. The apparatus of claim 13, wherein the TFI wires of the first and second light collection panels are used to electrically connect photovoltaic cells of the first and second light collection panels in parallel.

15. The apparatus of claim 13, wherein the TFI wires of the first and second light collection panels are used to electrically connect photovoltaic cells of the first and second light collection panels in series.

16. The apparatus of claim 1, wherein the apparatus is configured as one of a skylight, a window, a door, and a wall.

17. A method of manufacturing a photovoltaic light collecting apparatus, comprising:
providing a metallic frame assembly including a plurality of openings, wherein a portion of the frame assembly that surrounds each of the plurality of openings includes a cavity;
positioning at least one photovoltaic (PV) cell along at least a portion of the frame in each opening;
disposing in each of the plurality of openings a transmissive panel such that the frame assembly surrounds and supports each of the transmissive panels, each transmissive panel including
a first optical layer having a top surface and a bottom surface, the top surface including a plurality of micro-lenses configured to focus incident sunlight received thereon;
a second optical layer having a top surface and a bottom surface, the second optical layer disposed behind the first optical layer such that the bottom surface of the first optical layer is between the top surface of the first optical layer and the second optical layer and the top surface of the second optical layer is disposed facing the bottom surface of the first optical layer, the bottom surface of the second optical layer including a plurality of light turning features configured to redirect light incident thereon toward one or more edges of the second optical layer;
a gap between the first optical layer and the second optical layer,
wherein the at least one photovoltaic cell is disposed along at least one edge of the second optical layer such that the at least one photovoltaic cell receives light directed towards the edge of the second optical layer, the at least one photovoltaic cell having a first electrical output terminal and a second electrical output terminal;
disposing a first electrical bus and a second electrical bus in the cavity of the frame assembly; and
connecting the at least one photovoltaic cell to the first electrical bus and the second electrical bus using the first electrical output terminal and the second electrical output terminal, respectively.

18. The method of claim 17, wherein connecting the at least one photovoltaic cell comprises providing an electrical connection that passes through the frame assembly comprising the apparatus is configured as one of a skylight, a window, a door, and a wall.

19. The method of claim 17, wherein providing an electrical connection that passes through the frame assembly includes disposing the first electrical output terminal and the second electrical output terminal through at least one aperture of the frame assembly.

20. The method of claim 17, further comprising disposing wires within at least a portion of the light turning features and connecting the wires to the first electrical bus or the second electrical bus.

21. The method of claim 17, wherein the at least one photovoltaic cell includes a plurality of photovoltaic cells disposed on at least one edge of the second optical layer of the collection panels, and wherein the method further comprises coupling each of the plurality of photovoltaic cells along an edge of the second optical layer to a printed circuit board (PCB), wherein each respective PCB is configured to electrically coupled to the plurality of photovoltaic cells to connect the plurality of photovoltaic cells in serial, and wherein the first electrical output and the second electrical output provide electrical output terminals for power generated by the plurality of photovoltaic cells coupled to the PCB.
